(19) United States
(12) Patent Application Publication
(10) Pub. No.: US 2025/0327861 A1
(43) Pub. Date: Oct. 23, 2025

(54) CIRCUIT SELF TEST APPARATUS AND OPERATING METHOD THEREOF

(71) Applicant: SAMSUNG ELECTRONICS CO., LTD., Suwon-si (KR)

(72) Inventors: Sungho KANG, Suwon-si (KR); Jongho Park, Suwon-si (KR)

(73) Assignees: SAMSUNG ELECTRONICS CO., LTD., Suwon-si (KR); UIF (University Industry Foundation), Yonsei University, Seoul (KR)

(21) Appl. No.: 18/975,781

(22) Filed: Dec. 10, 2024

(30) Foreign Application Priority Data
Apr. 23, 2024 (KR) 10-2024-0054057

(51) Int. Cl. G01R 31/3177

(52) U.S. Cl. CPC G01R 31/3177

(57) ABSTRACT

A circuit self-test apparatus includes a circuit under test including a plurality of scan chains, where each of the plurality of scan chains includes a plurality of scan cells, and where each of the plurality of scan chains are configured based on a weight and a correlation obtained from a determination pattern input into each of the plurality of scan cells, and a test circuit including a linear feedback shift register (LFSR) configured to generate a random pattern for each of the plurality of scan chains, where the test circuit is configured to generate a modification pattern for each of the plurality of scan chains based on the random pattern and a state of the LFSR.

### CROSS-REFERENCE TO RELATED APPLICATION

This application is based on and claims priority to Korean Patent Application No. 10-2024-0054057, filed on Apr. 23, 2024, in the Korean Intellectual Property Office, the disclosure of which is incorporated by reference herein in its entirety.

### BACKGROUND

Example embodiments of the disclosure relate to a circuit self-test apparatus and an operating method thereof.

As the integration and structural complexity of a semiconductor process increases, defects which occur in the process increases, and a defect diagnosis is required to analyze the location and cause of the defects that occur in order to solve a yield reduction problem caused due to the increase of the defects. A scan-based test may be used as a method for detecting defects in the circuit. However, the scan-based test requires more scan cells to detect defects in the circuit as the circuit becomes larger, and as a result, the amount of data required for testing may rapidly increase.

The increase in the amount of test data may lead to the increase in test time and test costs. In addition, among the test data, there may be data which are ineffective in detecting a failure, so a failure detection probability may be reduced. As a result, a technology to reduce the amount of test data and the test time is required.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a test apparatus and a test method for detecting multiple defects in a scan chain in which multiple defects in a scan chain are capable of being detected with a small amount of test patterns and low power consumption.

Additional aspects will be set forth in part in the description which follows and, in part, will be apparent from the description, or may be learned by practice of the presented embodiments.

According to an aspect of an example embodiment, a circuit self-test apparatus may include a circuit under test including a plurality of scan chains, where each of the plurality of scan chains includes a plurality of scan cells, and where each of the plurality of scan chains are configured based on a weight and a correlation obtained from a determination pattern input into each of the plurality of scan cells, and a test circuit including a linear feedback shift register (LFSR) configured to generate a random pattern for each of the plurality of scan chains, where the test circuit is configured to generate a modification pattern for each of the plurality of scan chains based on the random pattern and a state of the LFSR.

According to an aspect of an example embodiment, an operating method of a circuit self-test apparatus may include determining a structure of a test circuit based on a structure of a circuit under test including a plurality of scan groups including a plurality of scan cells, where the plurality of scan groups are configured based on a weight and a correlation obtained from a determination pattern input into each of the plurality of scan cells, generating a modification pattern for each of the plurality of scan groups, performing a test for the circuit under test based on the modification pattern, receiving a response corresponding to the modification pattern from the circuit under test, and detecting a defect in the circuit under test based on the response.

According to an aspect of an example embodiment, an operating method of a circuit self-test apparatus may include obtaining, based on a determination pattern input into each of a plurality of scan cells, a weight for each of the plurality of scan cells, obtaining a correlation between a first scan cell among the plurality of scan cells and a second scan cell among the plurality of scan cells based on the determination pattern, and reconfiguring placement of the plurality of scan cells based on the weight and the correlation.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a circuit self-test apparatus according to one or more embodiments;

FIG. 2 is a flowchart illustrating a method for reconfiguring a structure of a circuit under test according to one or more embodiments;

FIG. 3 is a diagram illustrating an operation of obtaining a weight of the circuit under test according to one or more embodiments.

FIG. 4 is a diagram illustrating an operation of obtaining a correlation of the circuit under test according to one or more embodiments;

FIG. 5 is a diagram illustrating the circuit under test according to one or more embodiments;

FIG. 6 is a diagram illustrating a configuration of a test circuit according to one or more embodiments;

FIGS. 7 to 9 are diagrams illustrating a partial configuration of the test circuit according to one or more embodiments;

FIG. 10 is a diagram illustrating an output of a pattern selection multiplexer depending on a pattern selection signal according to one or more embodiments;

FIG. 11 is a diagram illustrating a selection signal generator according to one or more embodiments;

FIG. 12 is a diagram illustrating an output depending on an input of a group selection decoder according to one or more embodiments;

FIG. 13 is a flowchart illustrating an operation of the test circuit according to one or more embodiments;

FIG. 14 is a flowchart illustrating the operation of the test circuit according to one or more embodiments;

FIG. 15 is a diagram illustrating a test time of the circuit self-test apparatus, according to one or more embodiments; and

FIG. 16 is a diagram illustrating power consumption of the circuit self-test apparatus, according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

The terms of a singular form may include plural forms unless otherwise specified. Terms such as first, second, etc. may be used to describe various components, but are used only for the purpose of distinguishing one component from another component. These terms do not limit the difference in the material or structure of the components.

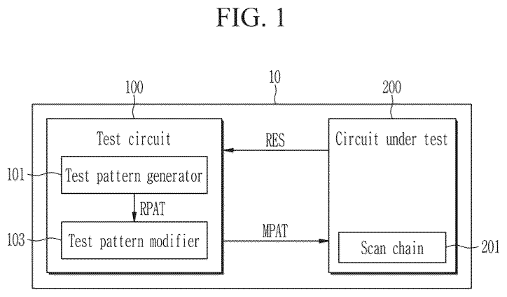

FIG. 1 is a diagram illustrating a circuit self-test apparatus according to one or more embodiments.

As illustrated in FIG. 1, the circuit self-test apparatus 10 may include a test circuit 100 and a circuit under test (CUT) 200.

The test circuit 100 may generate a modification pattern MPAT for detecting a defect of the CUT 200. The test circuit 100 may provide the modification pattern MPAT to the CUT 200, and may detect a response RES received from the CUT 200 to determine the defect of the CUT 200.

Specifically, the test circuit 100 may include a test pattern generator 101 and a test pattern modifier 103.

The test pattern generator 101 may generate a random pattern RPAT. The test pattern generator 101 may transfer the random pattern RPAT to the test pattern modifier 103.

The test pattern generator 101 may include a linear feedback shift register (LFSR) and a phase shifter. The LFSR may be a circuit that generates a pseudo random binary sequence of a binary bit string sequenced using a linear feedback. The test pattern generator 101 may generate the random pattern RPAT using the LFSR and the phase shifter. The random pattern RPAT generated by the test pattern generator 101 may be different based on a current state of the LFSR. The random pattern RPAT may be n patterns having k cycles.

The test pattern modifier 103 may modify the random pattern RPAT generated by the test pattern generator 101 to generate the modification pattern MPAT. The test pattern modifier 103 may transfer the modification pattern MPAT to the CUT 200. The modification pattern MPAT may be a pattern having the same k cycles as the random pattern RPAT.

Specifically, the test pattern modifier 103 may generate the modification pattern MPAT based on a structure of the CUT 200. In one or more embodiments, the modification pattern MPAT may be any one of the random pattern RPAT, a weight pattern modified by reflecting a weight to the random pattern RPAT, and shift-in data just previously output by the CUT 200.

The CUT 200 may include a plurality of scan chains 201. Each of the plurality of scan chains 201 may include a plurality of scan cells. Each of the plurality of scan cells may be reconfigured as the plurality of scan chains 201 based on a weight and a correlation obtained from a determination pattern.

The determination pattern may be a pattern for detecting the defect in the CUT 200. In one or more embodiments, the determination pattern may be generated by targeting the defect of the CUT 200 in an automatic test pattern generator (ATPG). When the CUT 200 is tested by using the determination pattern, a high defect detection rate and a high test coverage may be achieved. However, a large-capacity memory may be required for storing the determination pattern in a built-in self-test apparatus in order to perform a built-in self-test. The method for reconfiguring the structure of the CUT 200 will be described later.

The circuit self-test apparatus 10 according to one or more embodiments may autonomously test the CUT 200 using the modification pattern MPAT generated based on the structure of the CUT 200. The circuit self-test apparatus 10 may test the CUT 200 using the modification pattern MPAT for the plurality of scan chains 201 reconfigured based on the determination pattern to require a smaller-capacity memory. Further, scan cells which may detect the defect using a similar determination pattern may be disposed adjacent to each other to use the modification pattern MPAT in which logic state fluctuation of bits in the modification pattern MPAT is small. When the logic state fluctuation of the bits in the modification pattern MPAT is small, fluctuation of a flip generated a flip-flop in the scan cell may be reduced, such that power consumed upon test may be reduced.

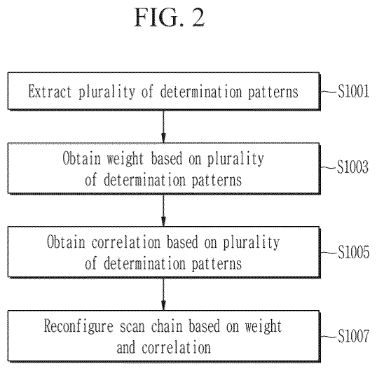

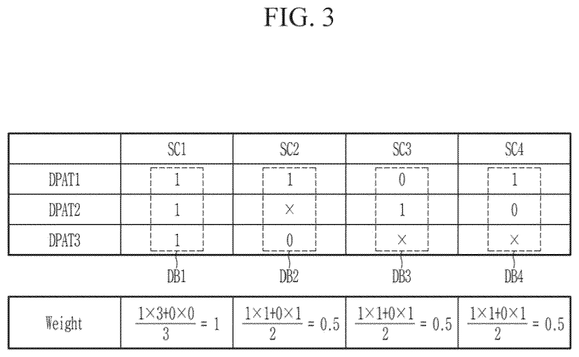

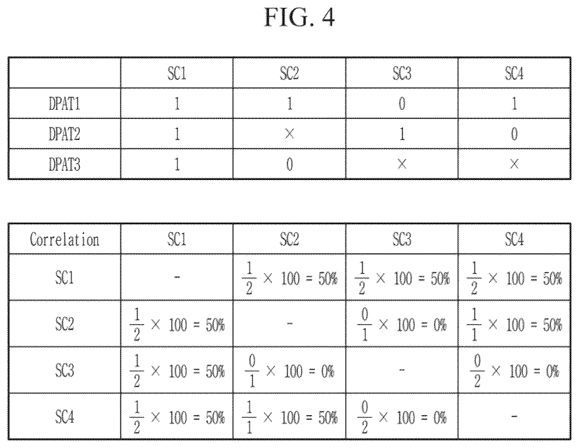

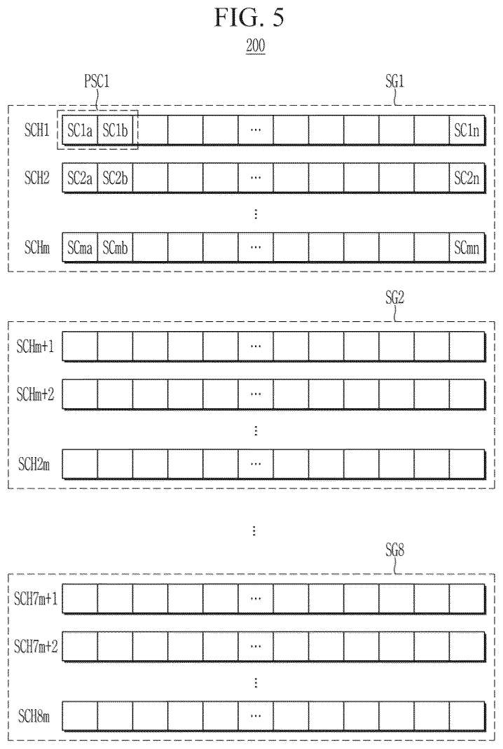

FIG. 2 is a flowchart illustrating a method for reconfiguring a structure of a CUT according to one or more embodiments. FIG. 3 is a diagram illustrating an operation of obtaining a weight of the CUT according to one or more embodiments. FIG. 4 is a diagram illustrating an operation of obtaining a correlation of the CUT according to one or more embodiments. FIG. 5 is a diagram illustrating the CUT according to one or more embodiments. Specifically, FIG. 5 is a diagram illustrating a reconfigured CUT according to one or more embodiments.

First, a plurality of determination patterns may be extracted in operation S1001.

Specifically, the automatic test pattern generator may generate a determination pattern corresponding to a length of the scan chain in the CUT 200. Each of the plurality of determination patterns may include a plurality of bits corresponding to the plurality of scan cells, respectively.

Referring to FIG. 3, a first determination pattern DPAT1, a second determination pattern DPAT2, and a third determination pattern DPAT3 may have a plurality of bits corresponding to a plurality of scan cells SC1, SC2, SC3, and SC4. A bit corresponding to a first scan cell SC1 may be referred to as a first bit DB1, a bit corresponding to a second scan cell SC2 may be referred to as a second bit DB2, a bit corresponding to a third scan cell SC3 may be referred to as a third bit DB3, and a bit corresponding to a fourth scan cell SC4 may be referred to as a fourth bit DB4.

For example, the first determination pattern DPAT1 may include the first bit DB1, the second bit DB2, and the fourth bit DB4 in a first logic state, and the third bit DB3 in a second logic state. The second determination pattern DPAT2 may include the first bit DB1 and the third bit DB3 in the first logic state, the fourth bit DB4 in the second logic state, and the second bit DB2 having any state. A bit represented by X which indicates a bit having any state may have one state of the first logic state and the second logic state. For example, the first logic state may be a logic ‘1’ or logic high state. For example, the second logic state may be a logic ‘0’ or logic low state. The third determination pattern DPAT3 may include the first bit DB1 in the first logic state, the second bit DB2 in the second logic state, and the third bit DB3 and the fourth bit DB4 having any state.

A weight may be obtained based on the plurality of determination patterns in operation S1003.

The weight may be a ratio value of dividing the number of bits having the first logic state among a plurality of bits corresponding to one scan cell among the plurality of scan cells SC1, SC2, SC3, and SC4 by the total number of plurality of bits corresponding to one scan cell. The bit having any state may not be considered when determining the weight. For example, a weight of the first scan cell SC1 may be a ratio of the number of first bits having the first logic state among a plurality of first bits DB1 corresponding to the first scan cell SC1.

Referring to FIG. 3, since three bits among the first bits DB1 have the first logic state, the first scan cell SC1 may have a weight of 3/3=1. Further, since one bit among the second bits DB2 has the first logic state, the second scan cell SC2 may have a weight of ½=0.5. Similarly, the third scan cell SC3 and the fourth scan cell SC4 may have the weight of ½=0.

The correlation may be obtained based on the plurality of determination patterns in operation S1005.

The correlation may be a value indicating a similarity between values of a plurality of first bits corresponding to the first scan cell among the plurality of scan cells SC1, SC2, SC3, and SC4, and values of a plurality of second bits corresponding to the second scan cell among the plurality of scan cells. The bit having any state may not be considered when determining the correlation. For example, a correlation between the first scan cell SC1 and the second scan cell SC2 may be a value indicating a similarity between the plurality of first bits DB1 corresponding to the first scan cell SC1 and the plurality of second bits DB2 corresponding to the second scan cell SC2.

Referring to FIG. 4, the first determination pattern DPAT1 may have the first bit DB1 and the second bit DB2 in the first logic state. The second determination pattern DPAT2 may have the first bit DB1 in the first logic state, and may have the second bit DB2 in any state. The third determination pattern DPAT3 may have the first bit DB1 in the first logic state, and may have the second bit DB2 in the second logic state. Since the logic states of the first bit DB1 and the second bit DB2 in the first determination pattern DPAT1 are the same as each other, the correlation between the first scan cell SC1 and the second scan cell SC2 may be ½*100=50%.

Similarly, correlations between the first scan cell SC1 and the third scan cell SC3, between the first scan cell SC1 and the fourth scan cell SC4, and between the second scan cell SC2 and the fourth scan cell SC4 may be 50%.

Since the second bit DB2 corresponding to the second scan cell SC2 and the third bit DB3 corresponding to the third scan cell SC3 do not include bits having the same logic state, the correlation between the second scan cell SC2 and the third scan cell SC3 may be 0%. Similarly, the correlation between the third scan cell SC3 and the fourth scan cell SC4 may be 0%.

The scan chain may be reconfigured based on the weight and the correlation in operation S1007.

In one or more embodiments, the plurality of scan cells SC1, SC2, SC3, and SC4 may be grouped into a plurality of scan groups based on the weight. Specifically, the plurality of scan cells SC1, SC2, SC3, and SC4 may be sequentially grouped into the scan groups based on the weight.

For example, a plurality of scan cells (i.e., when the bits in the first logic state among the bits corresponding to the scan cell among the plurality of determination patterns include a large number) having a high weight may be grouped into one scan group. For example, a plurality of scan cells (i.e., when the bits in the first logic state among the bits corresponding to the scan cell among the plurality of determination patterns include a low number) having a low weight may be grouped into one scan group.

Referring to FIG. 5, the CUT 200 may include a plurality of scan groups SG1, SG2, . . . , SG8. Each of the plurality of scan groups SG1, SG2, . . . , SG8 may include the same number of scan cells.

The scan cells having the high weight may be sequentially grouped into one scan group from a first scan group SG1. Except for the scan cells grouped into the first scan group SG1 among the plurality of scan cells, scan cells having the high weight among the remaining scan cells may be grouped into a second scan group SG2. In sequence, the plurality of scan cells may be grouped into the plurality of scan groups SG1, SG2, . . . , SG8.

In FIG. 5, it is illustrated that the plurality of scan cells are grouped into eight scan groups, but embodiments are not limited thereto, and the plurality of scan cells may be grouped into any number of scan groups.

In one or more embodiments, among the plurality of scan cells grouped into one scan groups, the plurality of scan cells may be configured as a cell pair based on the correlation. The cell pair may include two scan cells having a high correlation. Two scan cells configured as the cell pair may be disposed adjacent to each other. For example, the cell pair may be disposed adjacent to each other in one scan chain.

Specifically, any scan cell may be selected in one scan group. Thereafter, based on a correlation between the selected scan cell and the remaining scan cells other than the selected scan cell, an average value of the corresponding scan cell may be determined. For example, the average value of the corresponding scan cell may be a value acquired by adding all correlations between the selected scan cells and the remaining scan cells, and dividing the added value by the number of scan cells included in one scan group. The average value may be determined for all scan cells included in one scan group, and the cell pair may be configured based on the average value. For example, the cell pair may be configured sequentially from a scan cell having a lowest average value in one scan group. Specifically, a scan cell having a low average value and a scan cell having a highest correlation with the corresponding scan cell may be configured as one cell pair. Thereafter, a scan cell having a second lowest average value and a scan cell having a highest correlation with the corresponding scan cell may be configured as one cell pair. An operation of configuring the cell pair sequentially based on the average value may be repeated to configure all scan cells included in one scan group as the cell pair. Thereafter, a plurality of cell pairs may be included in one scan chain.

Referring to FIG. 5, the first scan group SG1 may include a first scan chain SCH1 to an m-th scan chain SCHm. The first scan chain SCH1 may include an 11-th scan cell SC1a to an n-th scan cell SC1n. The 11-th scan cell SC1a to the n-th scan cell SC1n included in the first scan chain SCH1 may be disposed adjacent to cell pairs corresponding thereto, respectively. For example, the 11-th scan cell SC1a and a 12-th scan cell SCb may be one cell pair.

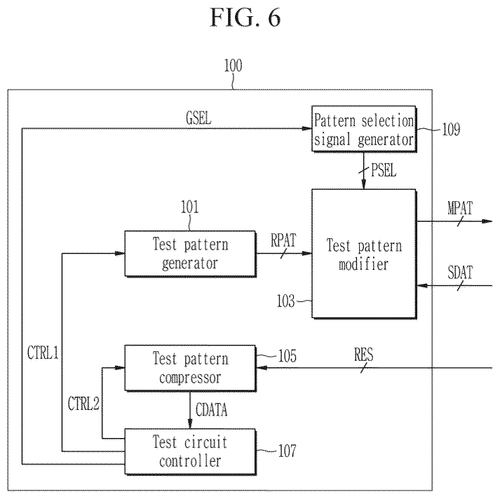

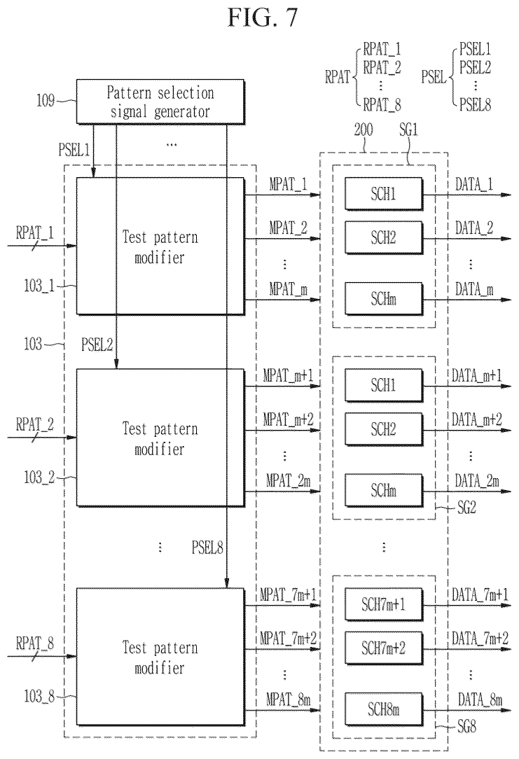

FIG. 6 is a diagram illustrating a configuration of a test circuit according to one or more embodiments. FIGS. 7 to 9 are diagrams illustrating a partial configuration of the test circuit according to one or more embodiments.

As illustrated in FIG. 6, the test circuit 100 may include a test pattern generator 101, a test pattern modifier 103, a test pattern compressor 105, a test circuit controller 107, and a pattern selection signal generator 109.

The test pattern generator 101 may generate a random pattern RPAT.

In one or more embodiments, the test pattern generator 101 may include an LFSR and a phase shifter. The test pattern generator 101 may shift the generated random pattern RPAT to the test pattern modifier 103. In one or more embodiments, the test pattern generator 101 may generate a random pattern RPAT corresponding to each of a plurality of scan chains.

The test pattern modifier 103 may modify the random pattern RPAT to generate a modification pattern MPAT.

Specifically, the test pattern modifier 103 may receive the random pattern RPAT from the test pattern generator 101. The test pattern modifier 103 may receive shift-in data SDAT from the CUT 200. Further, the test pattern modifier 103 may receive a pattern selection signal PSEL from the pattern selection signal generator 109. The test pattern modifier 103 may generate the modification pattern MPAT for the CUT 200 based on the pattern selection signal PSEL.

In one or more embodiments, the modification pattern MPAT may correspond to each of the plurality of scan chains in the CUT 200. The test pattern modifier 103 may generate the modification pattern MPAT and transfers the modification pattern MPAT to each of the plurality of scan chains SCH1 to SCH8m to derive a test to be performed by using the modification pattern MPAT in each of the plurality of scan chains SCH1 to SCH8m.

Referring to FIG. 7, the test pattern modifier 103 may include a plurality of test pattern modifiers 103_1, 103_2, . . . , 103_3 corresponding to the plurality of scan groups SG1, SG2, . . . , SG8, respectively.

A test pattern modifier 103_i (i may be one of natural numbers of 1 to 8) may receive a corresponding pattern selection signal PSELi from the pattern selection signal generator 109. As described below, a plurality of pattern selection multiplexers included in the test pattern modifier 103_i may operate based on one pattern selection signal PSELi.

The test pattern modifier 103i may receive a corresponding random pattern RPAT_i from the test pattern generator 101.

The test pattern modifier 103_i (i may be one of the natural numbers of 1 to 8) may generate a plurality of modification patterns MPAT based on the pattern selection signal PSELi and the random pattern RPAT_i. The plurality of modification patterns MPAT may correspond to the plurality of scan chains in a corresponding scan group SGi, respectively. Each of the plurality of scan chains in the scan group SGi may perform the test by using the plurality of modification patterns MPAT, and output a corresponding response.

Specifically, a first test pattern modifier 103_1 may receive a first pattern selection signal PSEL1 from the pattern selection signal generator 109, and receive a first random pattern RPAT_1 from the test pattern generator 101. The first test pattern modifier 103_1 may generate a plurality of first modification patterns MPAT_1, MPAT_2, . . . , MPAT_m based on the first random pattern RPAT_1 and the first pattern selection signal PSEL1. The plurality of first modification patterns MPAT_1, MPAT_2, . . . , MPAT_m may correspond to a plurality of scan chains SCH1, SCH2, . . . , SCHm in the first scan group SG1, respectively. The plurality of scan chains SCH1, SCH2, . . . , SCHm may perform the test by using the plurality of first modification patterns MPAT_1, MPAT_2, . . . , MPAT_m, and output corresponding responses RES_1, RES_2, . . . , RES_m, respectively.

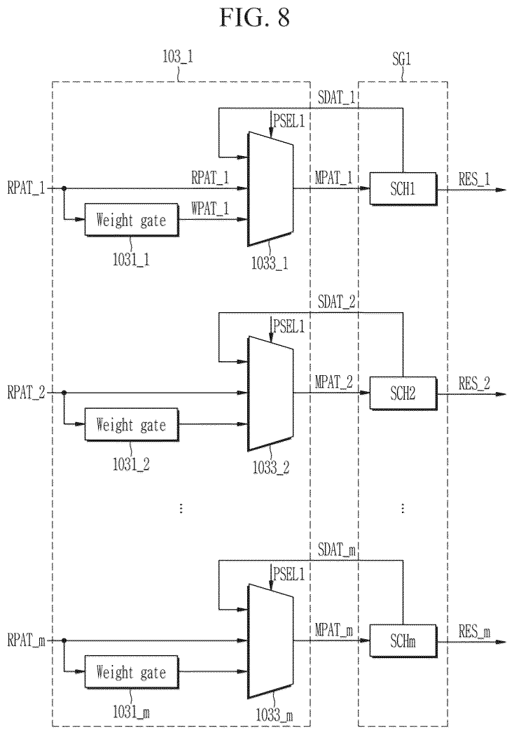

FIG. 8 is a diagram illustrating a configuration of the first test pattern modifier 103_1 according to one or more embodiments. A description of the configuration of the first test pattern modifier 103_1 may be applied to each of a second test pattern modifier 103_2 to an eighth test pattern modifier 103_8.

Referring to FIG. 8, the first test pattern modifier 103_1 may include a plurality of weight gates 1031_1, 1031_2, . . . , 1031_m and a plurality of pattern selection multiplexers 1033_1, 1033_2, . . . , 1033_m.

A first weight gate 1031_1 may be determined based on a weight of the scan group SG1 corresponding to the first test pattern modifier 103_1. In one or more embodiments, when the weight of the first scan group SG1 is equal to 0.5 or larger than 0.5 (e.g., 0.5 being a predetermined value), the first weight gate 1031_1 may be an OR GATE. In one or more embodiments, when the weight of the first scan group SG1 is smaller than 0.5, the first weight gate 1031_1 may be an AND gate.

In one or more embodiments, the first weight gate 1031_1 may include the OR gate and an AND gate, and may determine a gate type into which the random pattern RPAT_1 is input based on the weight.

The first weight gate 1031_1 may receive a corresponding random pattern RPAT_1 from the test pattern generator 101, and generate a first weight pattern WPAT_1 by performing a weight operation.

When the first weight gate 1031_1 is the OR gate, a probability that a bit of the random pattern RPAT_1 will be 0 is 50% and a probability that the bit of the random pattern RPAT_1 will be 1 is 50%, so a probability that the first weight pattern WPAT_1 will be 1 may be 0.5.

When the first weight gate 1031_1 is the AND gate, the probability that the bit of the random pattern RPAT_1 will be 0 is 50% and the probability that the bit of the random pattern RPAT_1 will be 1 is 50%, so the probability that the first weight pattern WPAT_1 will be 1 may be 0.25. That is, when the first weight gate 10311 is the AND gate, a probability that the first weight pattern WPAT_1 will be 0 may increase.

The first pattern selection multiplexer 1033_1 may output one input among a plurality of inputs as the first modification pattern MPAT_1 based on the first pattern selection signal PSEL1.

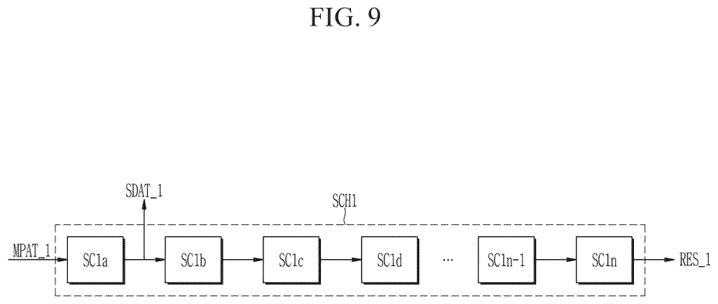

Specifically, a first pattern selection multiplexer 1033_1 may receive the random pattern RPAT_1 from the test pattern generator 101. The first pattern selection multiplexer 1033_1 may receive the first weight pattern WPAT_1 from the first weight gate 1031_1. The first pattern selection multiplexer 1033_1 may receive first shift-in data SDAT_1 from a corresponding scan chain among the plurality of scan chains SCH1, SCH2, . . . , SCHm in the first scan group SG1. A configuration of a first scan chain SCH1 among the plurality of scan chains SCH1, SCH2, . . . , SCHm will be described by jointly referring to FIG. 9.

FIG. 9 is a diagram illustrating the configuration of the first scan chain SCH1 according to one or more embodiments. The description of the first scan chain SCH1 may also be applied to a second scan chain SCH2 to an 8m-th scan chain SCH8m.

The first scan chain SCH1 may include a plurality of scan cells SC1a, . . . , SC1n. An 11-th scan cell SC1a positioned first among the plurality of scan cells SC1a, . . . , SC1n may receive the first modification pattern MPAT_1 from the test pattern modifier 103_1, and perform the test by using the first modification pattern MPAT_1 and transfer a result of the test to a 12-th scan cell SC1b.

The 12-th scan cell SC1b may perform the test by using the result of the test transferred from the 11-th scan cell SC1a, and transfer the result of the test to a 13-th scan cell SC1c.

An output of the 11-th scan cell SC1a may be the first shift-in data SDAT_1. That is, the first shift-in data SDAT_1 may be data just previously input into the 11-th scan cell SC1a. For example, when the bit in the first logic state as 2k−1 (k may be a natural number of 1 or more) is input into the 11-th scan cell SC1a, the first shift-in data SDAT_1 may be the bit in the first logic state in a 2k-th order.

Referring back to FIG. 8, the plurality of pattern selection multiplexers 1033_1, 1033_2, . . . , 1033_m may operate based on the same pattern selection signal PSEL1.

The test pattern compressor 105 may receive a response RES from the CUT 200, may capture the received response RES, and may compress captured data. The test pattern compressor 105 may transfer the compressed data CDATA to the test circuit controller 107.

In one or more embodiments, the test pattern compressor 105 may include a multi-input shift register.

The test circuit controller 107 may control components in the test circuit 100.

Specifically, the test circuit controller 107 may control an operation of the test pattern generator 101 through a first control signal CTRL1. For example, the test circuit controller 107 may control a random pattern shifting operation of the test pattern generator 101, a cycle of generating the random pattern RPAT, etc., based on the first control signal CTRL1.

Further, the test circuit controller 107 may control a data capture operation of the test pattern compressor 105 through a second control signal CTRL2.

The test circuit controller 107 may control a pattern selection signal generation operation of the pattern selection signal generator 109 through a group selection signal GSEL. The group selection signal GSEL may be a signal for selecting one scan group among the plurality of scan groups of the CUT 200. For example, the test circuit controller 107 may control one scan group among the plurality of scan groups to perform the test by using the random pattern RPAT through the group selection signal GSEL. In one or more embodiments, the test circuit controller 107 may change the group selection signal GSEL based on a predetermined cycle.

The test circuit controller 107 may detect a defect of the CUT 200 based on the compressed data CDATA received from the test pattern compressor 105.

The pattern selection signal generator 109 may generate the pattern selection signal PSEL based on the group selection signal GSEL. The pattern selection signal PSEL may be a signal for selecting a signal output as the modification pattern MPAT among a plurality of signals received by the test pattern modifier 103. For example, the pattern selection signal generator 109 may generate the pattern selection signal PSEL based on the cycles of the group selection signal GSEL and the random pattern RPAT.

The pattern selection signal generator 109 may transfer a pattern selection signal PSELi corresponding to the test pattern modifier 103_i, respectively.

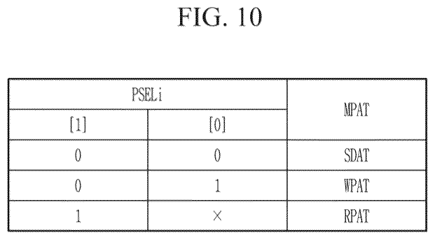

FIG. 10 is a diagram illustrating an output of a pattern selection multiplexer depending on a pattern selection signal according to one or more embodiments.

In one or more embodiments, the pattern selection signal PSEL may be a 2-bit signal. For example, a case is described in which, when the pattern selection signal PSEL1 is input into the first pattern selection multiplexer 1033_1 of the first test pattern modifier 103_1, the first pattern selection multiplexer 1033_1 operates.

For example, when a logic state of a most significant bit of the pattern selection signal; PSEL1 is ‘0’ and a logical state of a least significant bit is ‘0’, the first pattern selection multiplexer 1033_1 may output the first shift-in data SDAT_1 as the first modification pattern MPAT_1.

When the logic state of the most significant bit of the pattern selection signal; PSEL1 is ‘0’ and the logical state of the least significant bit is ‘1’, the first pattern selection multiplexer 10331 may output the first weight pattern WPAT_1 as the first modification pattern MPAT_1.

When the logic state of the most significant bit of the pattern selection signal; PSEL1 is ‘1’ and the logical state of the least significant bit is ‘0’ or ‘1’, the first pattern selection multiplexer 1033_1 may output the first random pattern RPAT_1 as the first modification pattern MPAT_1.

Thus, the first pattern selection multiplexer 1033_1 may output the first random pattern RPAT_1 when the most significant bit of the pattern selection signal PSEL1 is 1, and may output the first shift-in data SDAT_1 or the first weight pattern WPAT_1 according to the logic state of the least significant bit when the most significant bit of the pattern selection signal PSEL1 is 0.

In one or more embodiments, the pattern selection signal generator 109 may generate the pattern selection signal PSEL1 for controlling the corresponding pattern selection multiplexer 1033 so as to alternately output the weight pattern WPAT and the shift-in data SDAT. As a result, the pattern selection multiplexer 1033 may alternately output the weight pattern WPAT and the shift-in data SDAT (i.e., the weight pattern WPAT previously output by the pattern selection multiplexer 1033).

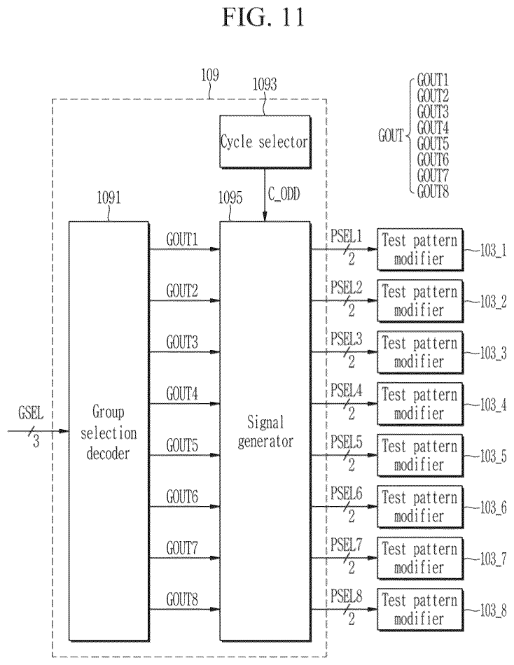

FIG. 11 is a diagram illustrating a selection signal generator according to one or more embodiments.

As illustrated in FIG. 11, the pattern selection signal generator 109 may include a group selection decoder 1091, a cycle selector 1093, and a signal generator 1095.

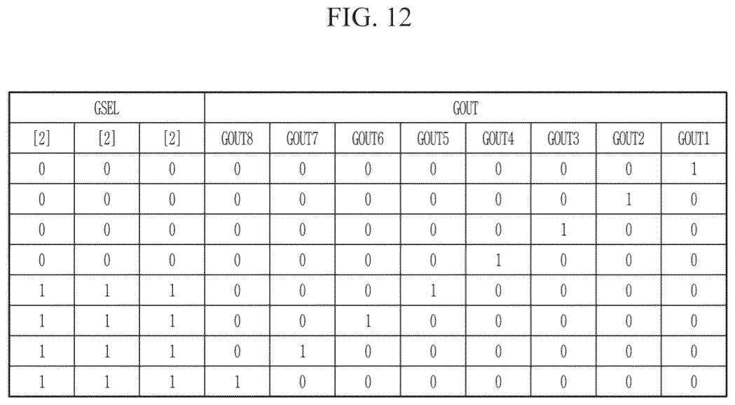

The group selection decoder 1091 may receive the group selection signal GSEL from the test circuit controller 107. The group selection signal GSEL may be a 3-bit signal. The group selection decoder 1091 may decode the group selection signal GSEL to generate a plurality of group output signals GOUT1 to GOUT8 corresponding to the plurality of scan groups SG1 to SG8, respectively. The group selection decoder 1091 may transfer the plurality of group output signals GOUT1 to GOUT8 to the signal generator 1095. The group selection decoder 1091 is described with reference to FIG. 12.

FIG. 12 is a diagram illustrating an output depending on an input of a group selection decoder according to one or more embodiments.

In one or more embodiments, the group selection decoder 1091 may select one scan group among the plurality of scan groups SG1 to SG8 based on the received group selection signal GSEL. As described later, the random pattern RPAT may be input into the selected scan group, and the weight pattern WPAT or the shift-in data SDAT may be alternately input into a scan group which is not selected. Hereinafter, the scan group determined to input the random pattern RPAT may be referred to as a random scan group, and a scan group determined to input another pattern may be referred to as a non-random scan group.

The group selection decoder 1091 may generate a group output signal GOUT having the first logic state to correspond to the selected scan group. As illustrated in FIG. 12, for example, the group selection decoder 1091 may generate a first group output signal GOUT1 having the first logic state and second to eighth group output signals GOUT2 to GOUT8 having the second logic state based on reception of a group selection signal GSEL indicating ‘000’. That is, the group selection decoder 1091 may select the first scan group SG1.

However, embodiments are not limited thereto, and the group selection decoder 1091 may select a plurality of scan groups among the plurality of scan groups SG1 to SG8 based on the group selection signal GSEL.

Referring back to FIG. 11, the cycle selector 1093 may generate cycle data C_ODD. The cycle selector 1093 may transfer the cycle data C_ODD to the signal generator 1095. The cycle data C_ODD may indicate whether an order of the bit in the modification pattern MPAT is a multiple of 2. For example, when the modification pattern MPAT is generated in the order of the multiple of 2, the cycle data C_ODD may have the second logic state. For example, when the modification pattern MPAT is not generated in the order of the multiple of 2, the cycle data C_ODD may have the first logic state. In one or more embodiments, the first logic state may be ‘1’ and the second logic state may be ‘0’.

The signal generator 1095 may receive a plurality of group selection signals GSEL1 to GSEL8 from the group selection decoder 1091. The signal generator 1095 may receive the cycle data C_ODD from the cycle selector 1093. The signal generator 1095 may generate the plurality of pattern selection signals PSEL1 to PSEL8 corresponding to the plurality of scan groups SG1 to SG8, respectively based on the plurality of group selection signals GSEL1 to GSEL8 and the cycle data C_ODD.

Specifically, the plurality of pattern selection signals PSEL1 to PSEL8 may be signals having logic states of the corresponding group output signals GOUT1 to GOUT8 as the logic state of the most significant bit, and having a logic state of the cycle data C_ODD as the logic state of the least significant bit, respectively. That is, referring to FIG. 10, the scan group selected based on the group output signals GOUT1 to GOUT8 may perform the test by using the random pattern RPAT, and a scan group which is not selected may perform the test by alternately using the weight pattern WPAT and the shift-in data SDAT.

In one or more embodiments, since only some scan groups among the plurality of scan groups SG1 to SG8 perform the test by using the random pattern RPAT, and the remaining scan groups perform the test by using the weight pattern WPAT and the shift-in data SDAT, a power reduction effect may be achieved while increasing a defect detection probability.

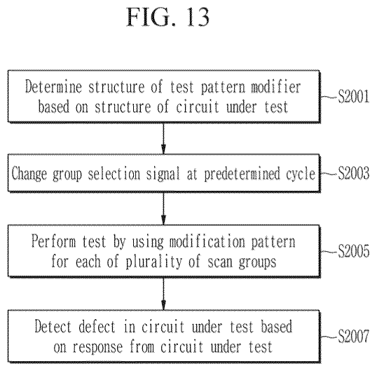

FIG. 13 is a flowchart illustrating an operation of the test circuit according to one or more embodiments.

First, the test circuit 100 may determine a structure of the test pattern modifier 103 based on a structure of the CUT 200 in operation S2001.

Specifically, the type of weight gate 1031 in the test pattern modifier 103 may be determined based on a weight of a corresponding scan group among the plurality of scan groups SG1 to SG8 in the CUT 200. In one or more embodiments, the test pattern modifier 103 may include the AND gate and the OR gate as the weight gate 1031. The test pattern modifier 103 may input the random pattern RPAT into the weight gate 1031 of the type determined based on the weight of the corresponding scan group.

The test circuit 100 may change the group selection signal GSEL at a predetermined cycle in operation S2003.

The pattern selection signal generator 109 may generate the pattern selection signal PSEL based on the group selection signal GSEL and the state of LFSR. Specifically, the pattern selection signal generator 109 may generate the pattern selection signal PSEL for controlling the test pattern modifier 103 so as alternately input the weight pattern WPAT and the shift-in data SDAT into the remaining scan groups among the plurality of scan groups SG1 to SG8 so as to input the random pattern RPAT into at least one scan group among the plurality of scan groups SG1 to SG8.

Since the generated random pattern RPAT varies depending on the state of LFSR in the test pattern generator 101, the scan group selected as the random scan group may be predetermined for each state of the LFSR. For example, when the state of the LFSR is changed at a specific cycle, the test circuit 100 may change the group selection signal GSEL based on the cycle at which the LFSR state is changed. As a result, the test circuit 100 may increase the detection probability of the defect in the CUT 200.

In one or more embodiments, the test circuit 100 may change the group selection signal GSEL based on a predetermined order. For example, the test circuit 100 may generate the group selection signal GSEL for controlling the test pattern modifier 103 to input the random pattern RPAT into a scan group which may detect the most defects when the random pattern RPAT is input among the plurality of scan groups SG1 to SG8.

The test circuit 100 may perform the test by using the modification pattern MPAT for each of the plurality of scan groups in operation S2005.

Thereafter, the test circuit 100 may detect the defect in the CUT 200 based on the response RES from the CUT 200 in operation S2007.

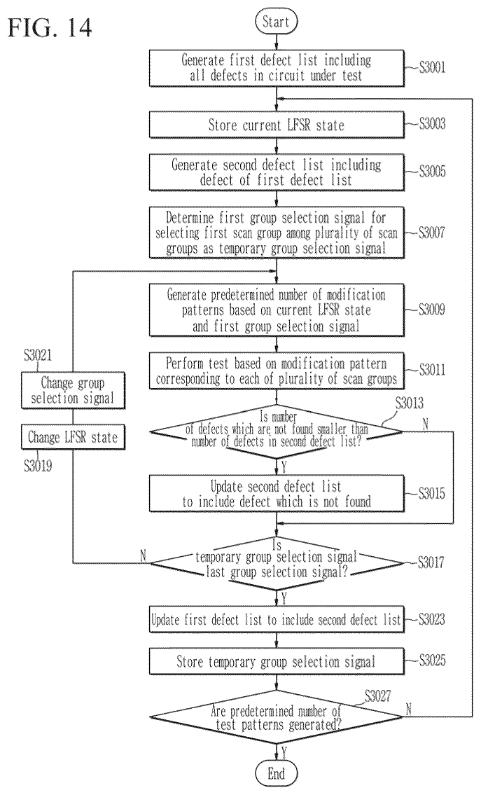

FIG. 14 is a flowchart illustrating the operation of the test circuit according to one or more embodiments. Specifically, FIG. 14 is a diagram illustrating a method for determining the random scan group.

In one or more embodiments, the method for determining the random scan group may be performed before the circuit self-test apparatus 10 is manufactured.

First, a first defect list including some or all defects in the CUT 200 may be generated in operation S3001.

The first defect list may include defect locations of some or all circuits connected to the plurality of scan groups SG1 to SG8 in the CUT 200, respectively.

A current LFSR state may be stored in operation S3003.

In one or more embodiments, the LFSR in the test pattern modifier 103 may have a plurality of states. The random pattern RPAT generated by the test pattern generator 101 may vary depending on the state of the LFSR. For example, when the test pattern modifier 103 generates a first random pattern in a first LFSR state, and generates a second random pattern in a second LFSR state, the first random pattern and the second random pattern may be different from each other.

A second defect list including the defect of the first defect list may be generated in operation S3005.

A first group selection signal for selecting a first scan group among the plurality of scan groups as the random scan group may be determined as a temporary group selection signal in operation S3007.

A pattern selection signal generated by the pattern selection signal generator 109 based on the first group selection signal may control the test pattern modifier 103 to input the random pattern RPAT into the first scan group, and may input the weight pattern WPAT or the shift-in data SDAT into scan groups other than the first scan group among the plurality of scan groups SG1 to SG8.

A predetermined number of modification patterns MPAT may be generated based on the current LFSR state and the first group selection signal in operation S3009.

The test pattern modifier 103 may receive the random pattern RPAT generated based on the current LFSR state from the test pattern generator 101, and receive the pattern selection signal PSEL generated based on the first group selection signal from the pattern selection signal generator 109. The test pattern modifier 103 may generate the modification pattern MPAT based on the random pattern RPAT and the pattern selection signal PSEL.

In one or more embodiments, the test pattern modifier 103 may generate modification patterns MPAT of a predetermined number T Thereafter, the test pattern modifier 103 may transfer the generated modification pattern MPAT to the CUT 200.

A test may be performed based on modification patterns MPAT corresponding to the plurality of scan groups SG1 to SG8 in operation S3011.

The plurality of scan groups SG1 to SG8 in the CUT 200 may receive the modification pattern MPAT, and perform the test based on the modification pattern MPAT. For example, each of the plurality of scan groups SG1 to SG8 may perform the test by receiving a predetermined number of modification patterns MPAT from the test pattern generator 101. The CUT 200 may generate a response RES indicating a result of the test based on performing the test. The CUT 200 may transfer the response RES to the test circuit 100.

In operation S3013, it may be determined whether the number of defects which are not found is smaller than the number of defects in the second defect list.

The test circuit 100 may receive the response RES by performing the test from the CUT 200, and the test circuit controller 107 may determine the number of defects which are found in the CUT 200 based on the response RES.

When the number of defects which are not found is smaller than the number of defects in the second defect list, the second defect list may be updated to include the defects which are not found in operation S3015.

Specifically, the second defect list may include a location of the defect which is not found. If the number of defects which are not found is greater than or equal to the number of defects in the second defect list, operation S3015 may be skipped.

In operation S3017, it may be determined whether the temporary group selection signal is a last group selection signal.

The test circuit controller 107 may determine that the temporary group selection signal is the last group selection signal when each of the plurality of scan groups completes performing the test as the random scan group. When even any one scan group among the plurality of scan groups SG1 to SG8 does not perform the test by using the random pattern, the test circuit controller 107 may determine that the temporary group selection signal is not the last group selection signal.

When the temporary group selection signal is not the last group selection signal, the LFSR state may be changed in operation S3019.

The test circuit controller 107 may change the LFSR state of the test pattern generator 101 to the LFSR state stored in operation S3003. The test pattern generator 101 may generate the random pattern RPAT based on the changed LFSR state.

Thereafter, the group selection signal may be changed S3021.

Next, operation S3009 may be performed again.

When the temporary group selection signal is the last group selection signal, the first defect list may be updated to the second defect list in operation S3023.

The temporary group selection signal may be stored in operation S3025.

Specifically, the most defects may be detected when performing the test with the modification pattern MPAT generated by using the temporary group selection signal stored for the corresponding LFSR state. That is, when the scan group indicated by the corresponding temporary group selection signal among the plurality of scan groups SG1 to SG8 is determined as the random scan group, the most defects may be detected in the CUT 200.

In operation S3027, it may be determined whether a predetermined number of test patterns are generated.

When it is determined that the predetermined number of test patterns are generated, the process may be terminated.

When it is determined the number of predetermined test patterns are not generated, operation S3003 may be performed again.

Thus, the test circuit 100 may generate a predetermined number of modification patterns MPAT while changing the group selection signal GSEL from the state of the LFSR in the test pattern generator 101. That is, the test circuit 100 may generate modification patterns MPAT in a number of patterns T which is a predetermined cycle for each state of the LFSR. The group selection signal GSEL of detecting the most defects in the CUT 200 may be stored for each LFSR state.

Thereafter, the test circuit 100 may generate the modification pattern MPAT by using the group selection signal GSEL predetermined based on the cycle at which the state of the LFSR is changed when performing the test of the CUT 200, and may perform the test by using the generated modification pattern MPAT. As a result, a defect detection speed may be increased, and a high defect detection probability may be achieved even with a small number of modification patterns.

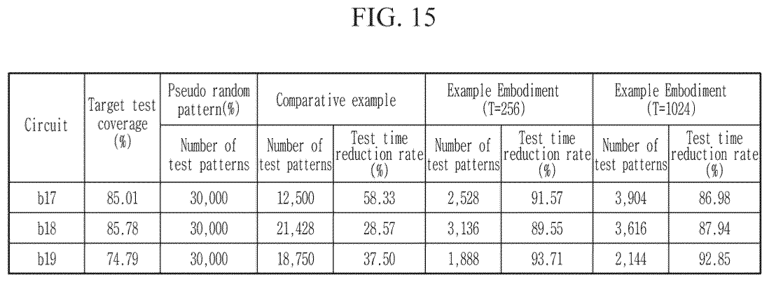

FIG. 15 is a diagram illustrating a test time of the circuit self-test apparatus, according to one or more embodiments.

In a comparative example, the test circuit may test a CUT by using a test pattern having one logic state at a specific cycle for some scan chains among all scan chains. A test coverage may be a ratio of defects detected with respect to all defects in the CUT.

As illustrated in FIG. 15, a defect of 85.01% may be detected by using 30000 patterns when performing the test for a circuit b17 by using a pseudo random pattern. In the comparative example, 12500 test patterns may be used in order to achieve the same test coverage, and a test time required for performing the test may be reduced by 58.33% compared to using the pseudo random pattern.

The test pattern as a pattern for detecting the defect of the CUT may be a modification pattern in the circuit self-test apparatus 10 according to FIGS. 1 to 14.

When the circuit self-test apparatus 10 according to one or more embodiments is set to generate 256 random patterns based on a state of one LFSR, the same test coverage may be achieved in spite of using 2528 test patterns, and the test time may be reduced by 91.57%. Further, when the circuit self-test apparatus 10 according to one or more embodiments is set to generate 1024 random patterns based on the state of one LFSR, the same test coverage may be achieved in spite of using 3904 test patterns, and the test time may be reduced by 86.98%.

Even when a circuit b18 and a circuit b19 are tested, the circuit self-test apparatus 10 according to one or more embodiments may confirm that the test time is reduced compared to the comparative example.

In summary, in the comparative example, the test time is reduced by 41.35% on average. However, when 1024 random patterns are set to be generated based on the state of one LFSR (i.e., when the group selection signal is changed with 1024 patterns as the cycle), the test time may be reduced by 89.26% on average. As a result, the circuit self-test apparatus 10 according to one or more embodiments may be enabled to be efficiently applied to an actually used self-test which requires failure detection with a high probability for a short test time.

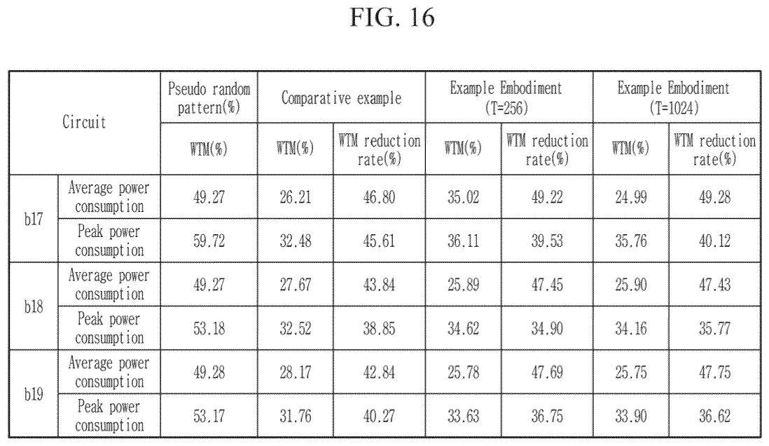

FIG. 16 is a diagram illustrating power consumption of the circuit self-test apparatus, according to one or more embodiments.

The power consumption may be measured based on weighted transition metric (WTM). The WTM may be a scan cell ratio in which data is inverted among all scan cells during one test pattern.

As illustrated in FIG. 16, when the test is performed for the circuit b17 by using the pseudo random pattern, power of 49.27% is consumed on average, and peak power consumption is 59.72%. According to the comparative example, when the test is performed for the circuit b17, power of 26.21% may be consumed on average, and the power consumption may be reduced by 46.80% compared to the case of using the pseudo random pattern. Further, according to the comparative example, when the test is performed for the circuit b17, the peak power consumption is 32.48%, and the peak power consumption may be reduced by 45.61% compared to the case of using the pseudo random pattern.

In a case where the circuit self-test apparatus 10 according to one or more embodiments is set to generate 256 random patterns based on the state of one LFSR, when the test is performed for the circuit b17, power of 35.02% may be consumed on average, and the power consumption may be reduced by 49.22% compared to the case of using the pseudo random pattern. Further, according to the comparative example, when the test is performed for the circuit b17, the peak power consumption is 36.11%, and the peak power consumption may be reduced by 39.53% compared to the case of using the pseudo random pattern. Further, in the case where the circuit self-test apparatus 10 according to one or more embodiments is set to generate 1024 random patterns based on the state of one LFSR, when the test is performed for the circuit b17, power of 24.99% may be consumed on average, and the power consumption may be reduced by 49.28% compared to the case of using the pseudo random pattern. Further, according to the comparative example, when the test is performed for the circuit b17, the peak power consumption is 35.76%, and the peak power consumption may be reduced by 40.12% compared to the case of using the pseudo random pattern.

In the circuit self-test apparatus 10 according to one or more embodiments, power consumption reduced by 48.15% may be achieved on average, and the peak power consumption may be reduced by 37.50% on average compared to the case of performing the test by using the pseudo random pattern. As a result, in the circuit self-test apparatus 10 according to one or more embodiments, a test having a higher defect detection probability with low power may be enabled.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A circuit self-test apparatus comprising:
a circuit under test comprising a plurality of scan chains, wherein each of the plurality of scan chains comprises a plurality of scan cells, and wherein each of the plurality of scan chains is configured based on a weight and a correlation obtained from a determination pattern input into each of the plurality of scan cells; and
a test circuit comprising a linear feedback shift register (LFSR) configured to generate a random pattern for each of the plurality of scan chains,
wherein the test circuit is configured to generate a modification pattern for each of the plurality of scan chains based on the random pattern and a state of the LFSR.

2. The circuit self-test apparatus of claim 1, wherein the determination pattern comprises a plurality of bits respectively corresponding to the plurality of scan cells,
wherein the correlation is determined based on a similarity between values of a plurality of first bits at a first location corresponding to a first scan cell among the plurality of scan cells and values of a plurality of second bits at a second location corresponding to a second scan cell among the plurality of scan cells, and
wherein the weight is a ratio value determined by dividing a number of bits in a first logic state among the plurality of first bits by a total number of first bits in the plurality of first bits.

3. The circuit self-test apparatus of claim 2, wherein the plurality of scan chains are grouped into a plurality of scan groups based on the weight,
wherein a first plurality of scan chains in a first scan group among the plurality of scan groups comprise the first scan cell and a third scan cell corresponding to the first scan cell that is determined based on the correlation, and
wherein the first scan cell is adjacent to the third scan cell in a corresponding scan chain among the first plurality of scan chains.

4. The circuit self-test apparatus of claim 3, wherein the modification pattern comprises a plurality of third bits, and
wherein the test circuit further comprises:
a test circuit controller configured to generate a group selection signal that selects at least one random scan group among the plurality of scan groups, wherein the group selection signal is predetermined to correspond to the state of the LFSR, and
a pattern selection signal generator configured to generate a pattern selection signal based on the group selection signal and based on an order of bits in the modification pattern being 2k-th, wherein k is an integer of 1 or more.

5. The circuit self-test apparatus of claim 4, wherein the test circuit further comprises:
a plurality of test pattern modifiers respectively corresponding to the plurality of scan chains, the plurality of test pattern modifiers comprising a first test pattern modifier corresponding to a first scan chain,
wherein the first test pattern modifier comprises:
a first weight gate configured to generate a first weight pattern based on a first random pattern corresponding to the first scan chain; and
a first pattern selection multiplexer configured to:
receive first shift-in data output from the first scan chain, the first random pattern, and the first weight pattern, and
output any one of the first shift-in data, the first random pattern, and the first weight pattern as a first modification pattern to the first scan chain based on the pattern selection signal.

6. The circuit self-test apparatus of claim 5, wherein, based on the group selection signal indicating that the first scan group is not a random scan group, the pattern selection signal is configured to control the first pattern selection multiplexer to alternately output the first shift-in data and the first weight pattern as the first modification pattern.

7. The circuit self-test apparatus of claim 5, wherein the plurality of test pattern modifiers comprise a second test pattern modifier corresponding to a second scan chain included in a second scan group among the plurality of scan groups,
wherein the second test pattern modifier comprises:
a second weight gate configured to generate a second weight pattern based on a second random pattern corresponding to the second scan chain, and
a second pattern selection multiplexer configured to:
receive second shift-in data output from the second scan chain, the second random pattern, and the second weight pattern, and
output any one of the second shift-in data, the second random pattern, and the second weight pattern as a second modification pattern to the second scan chain based on the pattern selection signal, and
wherein, based on the group selection signal indicating that the second scan group is a random scan group, the pattern selection signal is configured to control the second pattern selection multiplexer to output a random pattern corresponding to the second scan chain included in the second scan group as the modification pattern.

8. The circuit self-test apparatus of claim 5, wherein the first shift-in data is an output of the first scan cell among a plurality of scan cells included in the first scan chain.

9. The circuit self-test apparatus of claim 5, wherein the first weight gate is an OR gate based on a first weight corresponding to the first scan chain being greater than a predetermined value, and an AND gate based on the first weight being less than the predetermined value.

10. An operating method of a circuit self-test apparatus, comprising:
determining a structure of a test circuit based on a structure of a circuit under test comprising a plurality of scan groups comprising a plurality of scan cells, wherein the plurality of scan groups are configured based on a weight and a correlation obtained from a determination pattern input into each of the plurality of scan cells;
generating a modification pattern for each of the plurality of scan groups;
performing a test for the circuit under test based on the modification pattern;
receiving a response corresponding to the modification pattern from the circuit under test; and
detecting a defect in the circuit under test based on the response.

11. The operating method of claim 10, wherein the determination pattern comprises a plurality of bits respectively corresponding to the plurality of scan cells,
wherein the correlation is determined based on a similarity between values of a plurality of first bits at a first location corresponding to a first scan cell among the plurality of scan cells and values of a plurality of second bits at a second location corresponding to a second scan cell among the plurality of scan cells, and
wherein the weight is a ratio value determined by dividing a number of bits in a first logic state among the plurality of first bits by a total number of first bits in the plurality of first bits.

12. The operating method of claim 10, wherein each of the plurality of scan groups comprises a plurality of scan chains comprising at least one scan cell,
wherein the test circuit comprises a plurality of test pattern modifiers respectively corresponding to the plurality of scan chains, and
wherein the determining of the structure of the test circuit comprises determining that a first test pattern modifier corresponding to a first scan chain among the plurality of scan chains comprises an OR gate based on a first weight corresponding to the first scan chain being greater than a predetermined value and comprises an AND gate based on the first weight being less than the predetermined value.

13. The operating method of claim 12, wherein the generating of the modification pattern comprises:
generating, by a linear feedback shift register (LFSR), a plurality of random patterns respectively for the plurality of scan chains,
generating a group selection signal for selecting a random scan group among the plurality of scan groups based on a state of the LFSR,
generating a pattern selection signal based on the group selection signal and based on whether an order of bits in the modification pattern is 2k-th, wherein k is an integer of 1 or more, and
generating the modification pattern based on at least one random pattern of the plurality of random patterns and the pattern selection signal.

14. The operating method of claim 13, further comprising, prior to the generating of the pattern selection signal, receiving, by the first test pattern modifier, first shift-in data output from the first scan chain, a first random pattern corresponding to the first scan chain, and a first weight pattern generated based on the first random pattern,
wherein the generating of the pattern selection signal comprises generating the pattern selection signal for controlling the first test pattern modifier to alternately output the first shift-in data and the first weight pattern based on the group selection signal indicating that a first scan group among the plurality of scan groups is not a random scan group.

15. The operating method of claim 14, wherein the first shift-in data is an output of a first scan cell among a plurality of scan cells included in the first scan chain.

16. The operating method of claim 13, further comprising, prior to the generating of the pattern selection signal, receiving, by a second test pattern modifier corresponding to a second scan chain among the plurality of scan chains, second shift-in data output from the second scan chain, a second random pattern corresponding to the second scan chain, and a second weight pattern generated based on the second random pattern,
wherein the generating of the pattern selection signal comprises generating the pattern selection signal for controlling the second test pattern modifier to output the second random pattern based on the group selection signal indicating that a second scan group is a random scan group.

17. An operating method of a circuit self-test apparatus, comprising:
obtaining, based on a determination pattern input into each of a plurality of scan cells, a weight for each of the plurality of scan cells;
obtaining a correlation between a first scan cell among the plurality of scan cells and a second scan cell among the plurality of scan cells based on the determination pattern; and
reconfiguring placement of the plurality of scan cells based on the weight and the correlation.

18. The operating method of claim 17, wherein the determination pattern comprises a plurality of bits respectively corresponding to the plurality of scan cells,
wherein the correlation is determined based on a similarity between values of a plurality of first bits at a first location corresponding to the first scan cell among the plurality of scan cells and values of a plurality of second bits at a second location corresponding to the second scan cell among the plurality of scan cells, and
wherein the weight is a ratio value determined by dividing a number of bits in a first logic state among the plurality of first bits by a total number of first bits in the plurality of first bits.

19. The operating method of claim 17, wherein the reconfiguring placement of the plurality of scan cells comprises:
grouping the plurality of scan cells into a plurality of scan groups based on the weight, and
determining two scan cells among the plurality of scan cells in each of the plurality of scan groups as one cell pair based on the correlation.

20. The operating method of claim 19, wherein a plurality of first scan chains included in a first scan group among the plurality of scan groups comprises the first scan cell, and a third scan cell corresponding to the first scan cell that is determined based on the correlation, and
wherein the method further comprises, after the determining of two scan cells as one cell pair, placing the first scan cell adjacent to the third scan cell.
